(19) United States
(12) Patent Application Publication
(10) Pub. No.: US 2026/0282788 A1
(43) Pub. Date: Sep. 17, 2026

(54) PACKAGE METHOD AND PACKAGE SYSTEM

(71) Applicant: CXMT Corporation, Hefei (CN)

(72) Inventors: Shu WU, Hefei (CN); Hongkai JI, Hefei (CN); Heming ZHAO, Hefei (CN); Zhe WANG, Hefei (CN); CHIH-WEI CHANG, Hefei (CN); Kanyu CAO, Hefei (CN)

(21) Appl. No.: 19/428,340

(22) Filed: Dec. 22, 2025

Related U.S. Application Data
(63) Continuation of application No. PCT/CN2025/134845, filed on Nov. 14, 2025.

(30) Foreign Application Priority Data
Mar. 17, 2025 (CN) 202510323018.3

(51) Int. Cl. H10P 58/00; H10P 52/40; H10P 72/70; H10W 72/00; H10W 80/00; H10W 46/00

(52) U.S. Cl. CPC H10P 58/00; H10P 52/402; H10P 72/7416; H10W 72/07178; H10W 80/102; H10W 80/163; H10W 46/301; H10W 80/312; H10W 80/327

(57) ABSTRACT

Embodiments of the present disclosure relate to the semiconductor field, and provide a package method and a package system. The package method includes the following: A first wafer is provided. The first wafer includes multiple chips and a scribe line located between adjacent ones of the chips, and a first bonding surface is formed on front surfaces of the chips. The first wafer is diced along the scribe line to divide the first wafer into the multiple chips. A second wafer is provided. A second bonding surface is formed on a front surface of the second wafer. The second wafer is fixed above the multiple chips, so that the second bonding surface is disposed opposite to the first bonding surface. A bonding process is performed, to bond the second bonding surface of the second wafer to the first bonding surface of the multiple chips.

### CROSS-REFERENCE TO RELATED APPLICATIONS

This application is a continuation of International Patent Application No. PCT/CN2025/134845, filed on Nov. 14, 2025 which claims the benefit of Chinese Patent Application No. 202510323018.3, titled "PACKAGE METHOD AND PACKAGE SYSTEM ", filed with the China National Intellectual Property Administration (CNIPA) on Mar. 17, 2025, the disclosures of which are incorporated herein by reference in their entireties.

### TECHNICAL FIELD

The present disclosure relates to the semiconductor field, and in particular, to a package method and a package system.

### BACKGROUND

Semiconductor devices are employed in various electronic applications, e.g., a personal computer, a mobile phone, a digital camera, and another electronic device. Semiconductor devices are usually manufactured by successively depositing an insulating material layer or a dielectric material layer, a conductive material layer, and a semiconductor material layer over a semiconductor substrate, and patterning various material layers via photolithography to form circuit parts and elements on the various material layers. Dozens or hundreds of integrated circuits are usually manufactured on one semiconductor wafer, and then individual dies on the wafer are divided by dicing between the integrated circuits along lines. For example, the individual dies are usually packaged individually, in a multi-chip module, or in another type of package.

In terms of semiconductor packaging, a chip-to-wafer hybrid bonding technology is a core technology for implementing high-performance three-dimensional heterogeneous integration.

Currently, there are mainly two methods for implementing chip-to-wafer hybrid bonding. One is to transfer a chip to a wafer board and then perform wafer-to-wafer hybrid bonding, which is referred to as an indirect chip-to-wafer hybrid bonding method. The other is to directly bond the chip to the wafer, which is referred to as a direct chip-to-wafer hybrid bonding.

In comparison with the indirect chip-to-wafer hybrid bonding method, direct chip-to-wafer hybrid bonding has high bonding precision and flexible multilayer bonding processes. However, direct chip-to-wafer hybrid bonding is more sensitive to surface cleanliness of the chip, and is more difficult to implement. Currently, it is not possible to implement direct chip-to-wafer hybrid bonding via a complete and mature process flow.

### SUMMARY

Embodiments of the present disclosure provide a package method and a package system, to at least prevent impurities generated in a dicing procedure from affecting bonding of a chip to a second wafer.

According to some embodiments of the present disclosure, one aspect of the embodiments of the present disclosure provides a package method, including the following: A first wafer is provided. The first wafer includes multiple chips and a scribe line located between adjacent ones of the chips, and a first bonding surface is formed on front surfaces of the chips. The first wafer is diced along the scribe line to divide the first wafer into the multiple chips. A second wafer is provided. A second bonding surface is formed on a front surface of the second wafer. The second wafer is fixed above the multiple chips, so that the second bonding surface is disposed opposite to the first bonding surface. A bonding process is performed, to bond the second bonding surface of the second wafer to the first bonding surface of the multiple chips.

According to some embodiments of the present disclosure, another aspect of the embodiments of the present disclosure further provides a package system, configured to complete the foregoing package method, and including the following: a wafer processing equipment, configured to process a first wafer, to dice the first wafer into multiple chips, where front surfaces of the chips have a first bonding surface; and a package equipment, configured to fix a second wafer above the multiple chips, and bond a second bonding surface of the second wafer to the first bonding surface of the multiple chips.

### BRIEF DESCRIPTION OF DRAWINGS

One or more embodiments are exemplified with the figures in the accompanying drawings corresponding to the one or more embodiments. These example descriptions are not intended to limit the embodiments, and unless specifically stated, no scale limitations are constituted by the figures in the accompanying drawings. To describe the technical solutions in the embodiments of the present disclosure or the conventional technologies more clearly, the accompanying drawings required by the embodiments are briefly described below. Clearly, the accompanying drawings in the following description show merely some embodiments of the present disclosure, and other drawings may be obtained by a person of ordinary skill in the art from these accompanying drawings without creative efforts.

FIG. 1 is a flowchart corresponding to a package method according to an embodiment of the present disclosure;

FIG. 2 is a schematic structural diagram of a first wafer according to an embodiment of the present disclosure;

FIG. 3 is a schematic structural diagram of a chuck according to an embodiment of the present disclosure;

FIG. 4 is a schematic structural diagram of fixing a first wafer to a chuck according to an embodiment of the present disclosure;

FIG. 5 is a schematic structural diagram of a first wafer after being thinned according to an embodiment of the present disclosure;

FIGS. 6 and 7 are schematic structural diagrams before and after dicing a first wafer into multiple chips according to an embodiment of the present disclosure;

FIG. 8 is a schematic structural diagram of bonding multiple chips to a second wafer according to an embodiment of the present disclosure; and

FIG. 9 is a schematic structural diagram of a package system according to an embodiment of the present disclosure.

### DESCRIPTION OF EMBODIMENTS

The embodiments of the present disclosure are described in detail below with reference to the accompanying drawings. However, it may be understood by a person of ordinary skill in the art that in the embodiments of the present disclosure, many technical details are provided to enable readers to better understand the present disclosure. However, the technical solutions claimed in the present disclosure may be implemented even without these technical details and various variations and modifications made based on the following embodiments.

In a chip-to-wafer hybrid bonding technology, impurities are generated in a wafer dicing procedure. If these impurities shift between bonding surfaces in a bonding procedure, the reliability of a package product is affected when a bonding process is subsequently performed. In this case, how to improve bonding reliability becomes an urgent problem to be resolved.

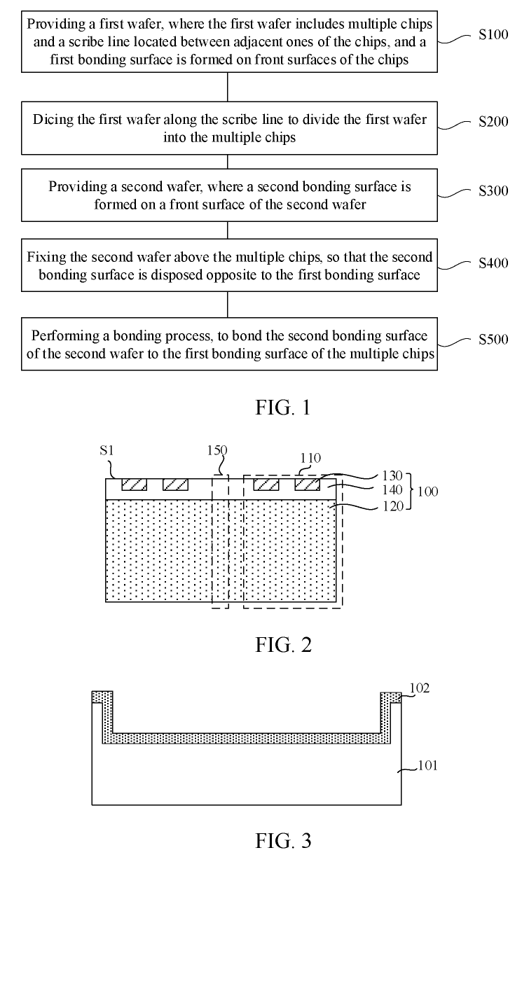

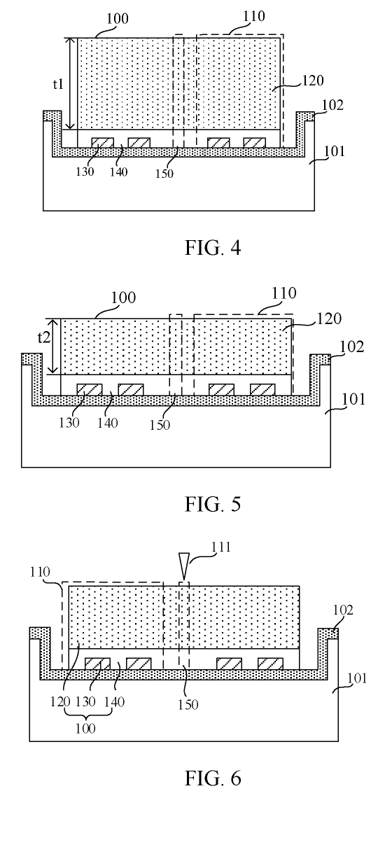

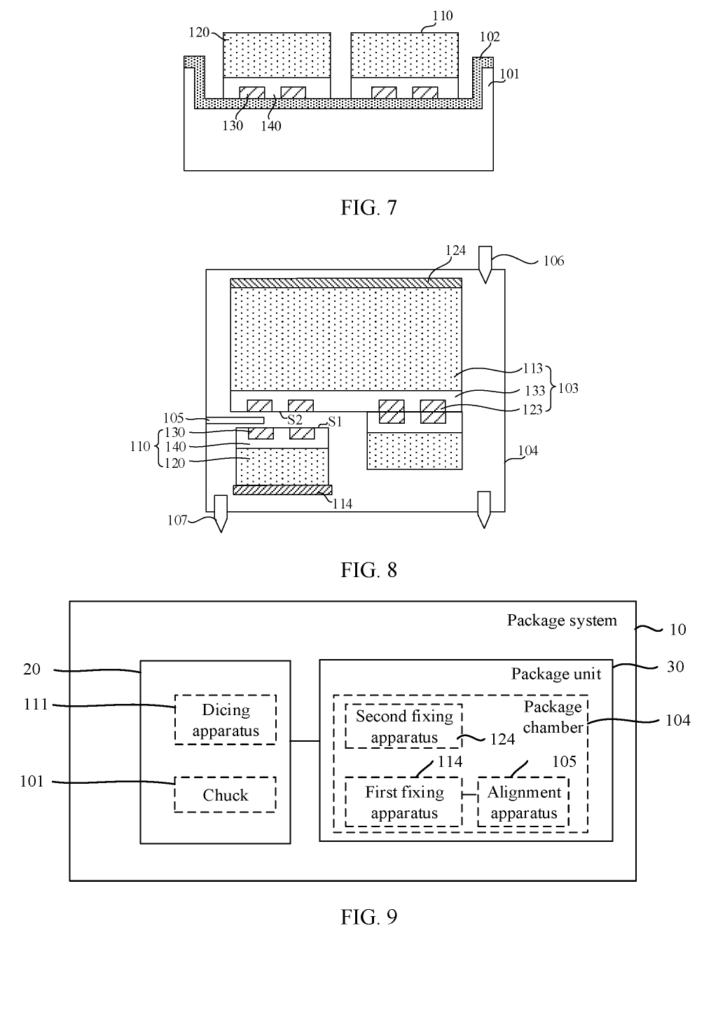

Therefore, to resolve the foregoing problem, an embodiment of the present disclosure proposes a new package method. The following describes the package method provided in this embodiment of the present disclosure with reference to the accompanying drawings. FIG. 1 is a flowchart corresponding to a package method according to an embodiment of the present disclosure. FIG. 2 is a schematic structural diagram of a first wafer according to an embodiment of the present disclosure. FIG. 3 is a schematic structural diagram of a chuck according to an embodiment of the present disclosure. FIG. 4 is a schematic structural diagram of fixing a first wafer to a chuck according to an embodiment of the present disclosure. FIG. 5 is a schematic structural diagram of a first wafer after being thinned according to an embodiment of the present disclosure. FIGS. 6 and 7 are schematic structural diagrams before and after dicing a first wafer into multiple chips according to an embodiment of the present disclosure. FIG. 8 is a schematic structural diagram of bonding multiple chips to a second wafer according to an embodiment of the present disclosure. The following describes the embodiments of the present disclosure in detail with reference to the accompanying drawings.

In step S100, a first wafer 100 is provided, where the first wafer 100 includes multiple chips 110 and a scribe line 150 located between adjacent ones of the chips 110, and a first bonding surface S1 is formed on front surfaces of the chips 110.

In some embodiments, referring to FIGS. 1 and 2, the multiple chips 110 are formed in the first wafer 100. The chip 110 may be a single die obtained after the first wafer 100 is diced, that is, a part implementing a function of the first wafer 100. The first wafer 100 further includes the scribe line 150 for dividing the multiple chips 110. The scribe line 150 is located in a blank region between the chips, and is employed for a subsequent dicing process, to separate the chips 110 from the wafer.

In step S200, the first wafer 100 is diced along the scribe line 150 to divide the first wafer 100 into the multiple chips 110.

In some embodiments, referring to FIGS. 2-7, the steps of dicing the first wafer 100 along the scribe line 150 may include the following: A chuck 101 is provided, and a coating film 102 is attached to the surface of the chuck 101. The first wafer 100 is fixed to the surface of the coating film 102, and the first wafer 100 is diced along the scribe line 150 to divide the first wafer 100 into the multiple chips 110. Dicing of the first wafer 100 may be implemented by mechanical dicing or laser dicing. For example, the chuck 101 may be an apparatus configured to carry the first wafer 100, and the first wafer 100 is fixed to the chuck 101, thereby facilitating operating the first wafer 100.

In some embodiments, referring to FIG. 3, before the first wafer 100 is fixed to the chuck 101, the method further includes the following: The coating film 102 is attached to the surface of the chuck 101. On the one hand, the coating film 102 can separate the first wafer 100 from the chuck 101, thereby preventing dirt on the surface of the chuck 101 from contaminating the first wafer 100. On the other hand, the coating film 102 has the bonding stability, which can fix the wafer while preventing the wafer from breaking due to dicing stress. In addition, in a procedure of dicing the first wafer 100, it is inevitable that some impurities fall off from the first wafer 100. By disposing the coating film 102, the some impurities can be fixed on the coating film 102 when the some impurities fall on the surface of the coating film 102, thereby preventing the some impurities from shifting and falling on the surface of a first bonding pad 130.

In some embodiments, the coating film 102 may be a UV film or a blue film. For example, when the coating film 102 is a UV film, since the UV film has decreased peeling viscosity after being irradiated by ultraviolet light, it is convenient to peel the divided chip 110 from the coating film 102, but the cost of the UV film is relatively high. When the coating film 102 is a blue film, the cost of the blue film is relatively low, but the blue film may produce adhesive residue due to a temperature influence. Generally, the UV film is usually employed for the first wafer 100 in a small size, and the blue film is usually employed for the first wafer 100 in a large size.

In some embodiments, referring to FIGS. 2-4, the step of fixing the first wafer 100 to the surface of the coating film 102 may include the following: The first bonding surface S1 is in contact with and fixed to the coating film 102. To be specific, the first bonding surface S1 is set toward a direction close to the chuck 101, so that the first bonding surface S1 can be protected. On the one hand, in a dicing procedure, the first bonding surface S1 is subjected to stress transmitted from a back surface, which can reduce the possibility of the first bonding surface S1 breaking in a dicing procedure. On the other hand, the first bonding surface S1 is set toward the chuck 101, so that the surface of the first bonding surface S1 can be blocked, thereby preventing impurities generated in the dicing procedure from falling on the first bonding surface S1, and further preventing the first bonding surface S1 from being contaminated and improving the reliability of subsequent bonding.

In some embodiments, after the first wafer 100 is diced along the scribe line 150, and the chip 110 is peeled from the coating film 102, the method further includes the following: The peeled chip 110 is cleaned to remove the adhesive residue of the coating film 102 on the surface of the chip 110.

In some embodiments, referring to FIGS. 4 and 5, the first wafer 100 may further include a first substrate 120. Before the first wafer 100 is divided into the multiple chips 110, the method further includes the following: A thinning process is performed on the first wafer 100, to obtain the chip 110 of a required thickness. For example, the thinning process may be chemical mechanical polishing (CMP, Chemical Mechanical Polishing). A part of the first substrate 120 of the first wafer 100 may be thinned in a direction from a back surface of the first wafer 100 to a front surface thereof, so that the thickness of the first substrate 120 of the first wafer 100 can be thinned from t1 to t2. A thinning thickness may be adjusted based on a packaging product requirement, to reduce the volume of a package structure. When the thinning process is performed, because the first bonding surface S1 is directly in contact with and fixed to the coating film 102, the surface of the first substrate 120 may be directly thinned, so that a location of the first wafer 100 does not need to be adjusted, to facilitate performing the thinning process.

In step S300, a second wafer 103 is provided, where a second bonding surface S2 is formed on a front surface of the second wafer 103.

In some embodiments, referring to FIG. 8, the second bonding surface S2 is formed on the front surface of the second wafer 103. The second wafer 103 may also include multiple second chips. However, for the second wafer 103, dicing does not need to be performed. It may be understood that a procedure of bonding the chip 110 to the second wafer 103 is a procedure of bonding the chip 110 to the second chip in the second wafer 103.

In some embodiments, referring to FIGS. 2-8, the first bonding surface S1 includes a first interlayer insulating layer 140 and a first bonding pad 130 embedded in the first interlayer insulating layer 140. The second bonding surface S2 includes a second interlayer insulating layer 133 and a second bonding pad 123 embedded in the second interlayer insulating layer 133. The first interlayer insulating layer 140 is a dielectric layer employed to isolate adjacent first bonding pads 130, and the second interlayer insulating layer 133 is a dielectric layer employed to isolate adjacent second bonding pads 123. The materials of the first interlayer insulating layer 140 and the second interlayer insulating layer 133 may be silicon dioxide SiO₂, an organosilicon carbon compound e.g., SiCOH, or a fluorine-doped oxide. The materials of the first bonding pad 130 and the second bonding pad 123 may be copper (Cu) or aluminum (Al). The first bonding pad 130 and the second bonding pad 123 may be microbumps or have flat surfaces flush with the surfaces of the first interlayer insulating layer 140 and the second interlayer insulating layer 133, to meet a bonding process requirement, e.g., thermocompression bonding.

In some embodiments, still referring to FIGS. 1-5, the chip 110 obtained after the first wafer 100 is diced may include the first substrate 120. The first interlayer insulating layer 140 and the first bonding pad 130 are located on the surface of the first substrate 120, that is, the first bonding surface S1 is formed on the front surface of the chip 110. The second wafer 103 may include a second substrate 113, the second interlayer insulating layer 133 and the second bonding pad 123 are located on the surface of the second substrate 113. Multiple circuit structures, e.g., a transistor structure, a word line, and a bit line, may be formed in the first substrate 120 and the second substrate 113, to implement a function of a memory cell or a logic circuit. For example, in a memory chip, a word line and a bit line may be employed to address a memory cell, and a transistor structure may serve as a core part of the memory cell to store data. In addition, the first substrate 120 and the second substrate 113 may further integrate other circuit modules, e.g., a logic control circuit and an input/output circuit, to implement a complete logic operation function of the chip.

In step S400, the second wafer 103 is fixed above the multiple chips 110, so that the second bonding surface S2 is disposed opposite to the first bonding surface S1.

In some embodiments, referring to FIG. 8, in a bonding procedure, the second wafer 103 may be fixed above the chip 110, so that the second bonding surface S2 is disposed opposite to the first bonding surface S1. Specifically, the second bonding pad 123 and the second interlayer insulating layer 133 are disposed opposite to the first bonding pad 130 and the first interlayer insulating layer 140 of the chip 110, that is, the first bonding surface S1 faces upward. In this case, in the bonding procedure, because the first bonding surface S1 faces upward, the impurities generated in the procedure of dividing the first wafer 100 move away from the first bonding surface S1 under the influence of gravity, thereby preventing the impurities from falling between the first bonding surface S1 and the second bonding surface S2, and further improving the reliability of a semiconductor structure after bonding.

In step S500, a bonding process is performed, to bond the second bonding surface S2 of the second wafer 103 to the first bonding surface S1 of the multiple chips 110.

In some embodiments, still referring to FIGS. 7 and 8, after dicing of the first wafer 100 is complete, the multiple chips 110 may be separately conveyed, via a conveyor belt, to a chamber in which the chuck 101 is located. After the chip 110 is picked up, a direction of the chip 110 may be further adjusted, so that the first bonding surface S1 is disposed opposite to the second bonding surface S2 of the second wafer 103 fixed above the chip 110. In the bonding procedure, the chip 110 is moved until the first bonding surface S1 is in contact with the second bonding surface S2 of the second wafer 103, so that the chip 110 is bonded to the second wafer 103. Then, an annealing process is performed to complete bonding.

Specifically, the first bonding surface S1 includes the first interlayer insulating layer 140 and the first bonding pad 130 embedded in the first interlayer insulating layer 140, and the second bonding surface S2 includes the second interlayer insulating layer 133 and the second bonding pad 123 embedded in the second interlayer insulating layer 133. The bonding the second bonding surface S2 of the second wafer 103 to the first bonding surface S1 of the multiple chips 110 may include the following: The first interlayer insulating layer 140 of the first bonding surface S1 is bonded to the second interlayer insulating layer 133 of the second bonding surface S2, and the first bonding pad 130 of the first bonding surface S1 is bonded to the second bonding pad 123 of the second bonding surface S2. In other words, the chip 110 may be bonded to the second wafer 103 in a hybrid bonding manner. In the bonding procedure, the first interlayer insulating layer 140 of the first bonding surface S1 may be first bonded to the second interlayer insulating layer 133 of the second bonding surface S2 at a first bonding temperature. The first bonding pad 130 of the first bonding surface S1 is then bonded to the second bonding pad 123 of the second bonding surface S2 at a second bonding temperature. Because expansion coefficients of the first bonding pad 130 and the second bonding pad 123 are greater than expansion coefficients of the first interlayer insulating layer 140 and the second interlayer insulating layer 133, the first bonding pad 130 and the second bonding pad 123 continue to expand in a high temperature annealing procedure, thereby filling a gap between the first bonding pad 130 and the second bonding pad 123, and implementing final bonding. The first bonding temperature and the second bonding temperature may be the same or different, and ranges of the first bonding temperature and the second bonding temperature may both be 100–400℃.

In some embodiments, in the bonding procedure, the method may further include the following: The surface of the chip 110 and the surface of the second wafer 103 are first activated via a plasma activation process, to implement hydrophilic oxide-oxide (Hydrophilic oxide-oxide) bonding, thereby improving the contact performance of a bonding interface.

In some embodiments, referring to FIG. 8, after the bonding of one chip 110 to the second wafer 103 is complete, the method further includes the following: Bonding of the remaining chips 110 to the second wafer 103 continues, to finally complete bonding of the multiple chips 110 to the second wafer 103.

In some embodiments, referring to FIG. 8, in the bonding procedure, gas injection processing and gas extraction processing may be further performed. A gas flow direction of the gas injection processing is a direction from the second wafer 103 toward the chips 110, and a gas extraction speed of the gas extraction processing is greater than a gas injection speed of the gas injection processing. Specifically, the gas injection processing is performed, and the gas flow direction of the gas injection processing is the direction from the second wafer 103 toward the chips 110, to blow away the impurities toward a direction away from the first bonding surface S1. Setting the gas extraction processing can further avoid an excessive gas pressure in an accommodation chamber accommodating the chip 110 and the second wafer 103. In addition, the gas extraction processing can further remove the impurities blown by the gas injection processing from the accommodation chamber of the chip 110 and the second wafer 103. In addition, the gas extraction speed of the gas extraction processing is set to be greater than the gas injection speed of the gas injection processing, so that a negative pressure can be maintained in the accommodation chamber in which the chip 110 and the second wafer 103 are located. Therefore, it can be ensured, as far as possible, that the impurities blown by the gas injection processing are removed from the accommodation chamber in which the chip 110 and the second wafer 103 are located. In a procedure of dicing the first wafer 100, particle impurities generated during dicing may be attached to a side wall of the formed chip 110. The foregoing gas injection processing and gas extraction processing operations can effectively prevent the particle impurities generated in the procedure of wafer dicing from falling between the first bonding surface S1 and the second bonding surface S2, thereby improving the reliability of bonding between the chip 110 and the second wafer 103.

Further, the gas injection processing can further purify a gas environment of the bonding process, thereby preventing the surfaces of the first bonding surface S1 and the second bonding surface S2 from being contaminated in the bonding procedure. For example, a gas introduced in the gas injection processing may be an inert gas or nitrogen. For example, the inert gas may be helium or argon. The cost of nitrogen is relatively low and also has a relatively stable chemical property, thereby improving the safety and the reliability of the entire package method. In addition, the flow rate of the introduced gas may be in the range of 300–2000 sccm, and the flow rate of gas extraction in the gas extraction processing may be in the range of 500–2500 sccm. When the flow rate of the introduced gas is less than 300 sccm, there may be a problem that the gas environment of the entire bonding process cannot be purified and cleaned. When the flow rate of the introduced gas is greater than 2000 sccm, a waste of the gas flow may occur due to an excessively large gas flow, and a deviation of the chip 110 may occur due to the excessively large gas flow of the introduced gas. For the gas extraction processing, an excessively small flow rate of gas extraction may cause a failure to ensure that the impurities are removed from the accommodation chamber in which the chip 110 and the second wafer 103 are located. An excessively large flow rate of gas extraction may further excessively increase costs, causing a high cost of the entire manufacturing process.

In this embodiment of the present disclosure, the first wafer 100 is divided to obtain the multiple separated chips 110, and the second wafer 103 is fixed above the chips 110, so that the first bonding surface S1 is disposed opposite to the second bonding surface S2. Then, the bonding process is performed, so that the impurities do not fall between the first bonding surface S1 and the second bonding surface S2 due to a gravity factor, thereby improving the reliability of bonding between the chip 110 and the second wafer 103.

Another embodiment of the present disclosure further provides a package system, which may be employed to complete the package method in the foregoing some or all embodiments. FIG. 9 is a schematic structural diagram of a package system according to an embodiment of the present disclosure. The following describes the package system provided in the another embodiment of the present disclosure with reference to the accompanying drawings. It should be noted that for the same part or a corresponding part as the foregoing embodiment, refer to the foregoing embodiment. Details are not described in the following.

In some embodiments, referring to FIGS. 8 and 9, the package system 10 may include a wafer processing equipment 20, configured to process a first wafer 100, to dice the first wafer 100 into multiple chips 110, where front surfaces of the chips 110 have a first bonding surface S1; and a package equipment 30, configured to fix a second wafer 103 above the multiple chips 110, and bond a second bonding surface S2 of the second wafer 103 to the first bonding surface S1 of the multiple chips 110. For example, the wafer processing equipment 20 may include a chuck 101, where the chuck 101 is configured to carry the first wafer; and a dicing apparatus 111, where the dicing apparatus 111 is configured to dice the first wafer 100 into the multiple chips 110. For example, the dicing apparatus 111 may be a mechanical blade or a laser emitter. The mechanical blade has a relatively low dicing cost, but may cause the chip 110 to chip or crack, causing damage to a product. In this case, a buffer member may be further installed on the chuck 101 to provide additional support for the first wafer 100, thereby preventing the diced chip 110 from being broken. Laser dicing is applicable to the first wafer 100 with a relatively thin thickness, so that stress to which the first wafer 100 is subject can be reduced, and the probability of chipping or cracking of the chip 110 can be reduced, thereby improving the yield of a dicing process. In addition, because a laser beam can focus on a light spot in a relatively small size, a complex dicing pattern can be implemented, and the chips 110 can be separated at the minimum spacing.

In some embodiments, still referring to FIGS. 8 and 9, the package equipment 30 may include the following: a first fixing apparatus 114, where the first fixing apparatus 114 is configured to fix the chips 110 of the first wafer 100; an alignment apparatus 105, configured to align the second wafer 103 with the chips 110, where the first bonding surface S1 of the chips 110 has a first alignment mark, the second bonding surface S2 of the second wafer 103 has a second alignment mark, and the alignment apparatus 105 is configured to detect the first alignment mark and the second alignment mark, and control the first fixing apparatus 114 to align the first alignment mark with the second alignment mark; a second fixing apparatus 124, where the second fixing apparatus 124 is configured to fix the second wafer 103, and the second fixing apparatus 124 is located above the first fixing apparatus 114; and a package chamber 104, where the package chamber 104 includes a gas injection apparatus 106 and a gas extraction apparatus 107, and the first fixing apparatus 114, the second fixing apparatus 124, and the alignment apparatus 105 are disposed in the package chamber 104. For example, the second fixing apparatus 124 may be a vacuum adsorption platform or an electrostatic adsorption platform, and the second wafer 103 may be fixed through vacuum adsorption or electrostatic adsorption. The first fixing apparatus 114 may be a vacuum sucker. After entering the package chamber 104, the chip 110 is fixed by the first fixing apparatus 114. The second fixing apparatus 124 is located above the first fixing apparatus 114, so that the second wafer can be fixed above the chip 110, and the second bonding surface S2 is disposed opposite to the first bonding surface S1. In addition, by controlling the first fixing apparatus 114 to move to the second fixing apparatus 124, bonding of the second bonding surface S2 to the first bonding surface S1 can be complete, and bonding of the chip 110 to the second wafer 103 is complete via an annealing process.

Before the chip 110 is bonded to the second wafer 103, the following is further included: The chip 110 is aligned with the second wafer 103. For example, several first alignment marks and several second alignment marks may be disposed on the first bonding surface S1 of the chip 110 and the second bonding surface S2 of the second wafer 103. The alignment apparatus 105 may obtain a location of the first alignment mark and a location of the second alignment mark, and generate corresponding location information based on the location of the first alignment mark and the location of the second alignment mark. After obtaining the location information, the first fixing apparatus 114 may adjust a location corresponding to the first fixing apparatus 114, so that the first bonding surface S1 of the chip 110 is enabled to be aligned with the second bonding surface S2 of the second wafer 103, thereby improving the alignment precision and the bonding reliability of a bonding procedure.

It should be noted that the alignment apparatus 105 shown in FIG. 8 is disposed between the chip 110 and the second wafer 103. Actually, it is only for ease of understanding the schematic diagram. The alignment apparatus 105 may be disposed between the chip 110 and the second wafer 103 when the first alignment mark and the second alignment mark are being obtained, and may be further retracted between the chip 110 and the second wafer 103 after obtaining is complete.

In some embodiments, for the gas injection apparatus 106, the gas injection apparatus 106 is fixed to the top of the package chamber 104, namely, a side of the second fixing apparatus 124 away from the first fixing apparatus 114, and is configured to supply gas to the package chamber 104. For the gas extraction apparatus 107, the gas extraction apparatus 107 is fixed to the bottom of the package chamber 104, namely, a side of the first fixing apparatus 114 away from the second fixing apparatus 124, and is configured to extract gas in the package chamber 104.

The gas injection apparatus 106 is configured to continuously provide gas to the package chamber 104 in a bonding procedure, to blow away impurities, generated in a procedure of dicing the first wafer 100, toward a direction away from the first bonding surface S1, thereby preventing the impurities from falling between the first bonding surface S1 and the second bonding surface S2, and further improving the bonding reliability. The gas extraction apparatus 107 is configured to continuously remove gas in the package chamber 104 in the bonding procedure. The gas extraction apparatus 107 may further remove, from the package chamber 104, impurities blown away by the gas injection apparatus 106, thereby further preventing the impurities from falling between the first bonding surface S1 and the second bonding surface S2. Gas extraction apparatuses 107 may be evenly disposed below the first fixing apparatus 114, so that a gas flow in a gas extraction procedure is evenly extracted in any direction, thereby preventing an impurity particle from moving between the chips, and further improving the bonding reliability.

A person of ordinary skill in the art may understand that the foregoing implementations are specific embodiments for implementing the present disclosure. In actual application, various modifications may be made to the forms and details of the implementations without departing from the scope of the embodiments of the present disclosure. Any person skilled in the art may make changes and modifications without departing from the scope of the embodiments of the present disclosure. Therefore, the protection scope of the embodiments of the present disclosure shall be subject to the scope defined by the claims.

What is claimed is:

1. A package method, comprising:
providing a first wafer, the first wafer comprising a plurality of chips and a scribe line located between adjacent ones of the chips, and a first bonding surface being formed on front surfaces of the chips;
dicing the first wafer along the scribe line to divide the first wafer into the plurality of chips;
providing a second wafer, a second bonding surface being formed on a front surface of the second wafer;
fixing the second wafer above the plurality of chips, so that the second bonding surface is disposed opposite to the first bonding surface; and
performing a bonding process, to bond the second bonding surface of the second wafer to the first bonding surface of the plurality of chips.

2. The package method according to claim 1, wherein the first bonding surface comprises a first interlayer insulating layer and a first bonding pad embedded in the first interlayer insulating layer, and the second bonding surface comprises a second interlayer insulating layer and a second bonding pad embedded in the second interlayer insulating layer.

3. The package method according to claim 2, wherein the bonding the second bonding surface of the second wafer to the first bonding surface of the plurality of chips comprises:
bonding the first interlayer insulating layer to the second interlayer insulating layer and the first bonding pad to the second bonding pad.

4. The package method according to claim 1, wherein the bonding process further comprises: performing gas injection processing and gas extraction processing in a bonding procedure, wherein a gas flow direction of the gas injection processing is a direction from the second wafer toward the chips, and a gas extraction speed of the gas extraction processing is greater than a gas injection speed of the gas injection processing.

5. The package method according to claim 4, wherein process parameters of the gas injection processing comprise: an inert gas or nitrogen is introduced, and a flow rate of the introduced gas is 300–2000 sccm, and a process parameter of the gas extraction processing comprises: a flow rate of gas extraction is 500–2500 sccm.

6. The package method according to claim 1, wherein the step of dicing the first wafer along the scribe line comprises:
providing a chuck, and attaching a coating film to a surface of the chuck; and
fixing the first wafer to a surface of the coating film, and dicing the first wafer along the scribe line to divide the first wafer into the plurality of chips.

7. The package method according to claim 6, wherein the step of fixing the first wafer to a surface of the coating film comprises contacting and fixing the first bonding surface to the coating film.

8. The package method according to claim 1, before the dividing the first wafer into the plurality of chips, further comprising performing a thinning process on the first wafer.

9. A package system, configured to complete the package method according to claim 1, and comprising:
a wafer processing equipment, configured to process a first wafer, to dice the first wafer into a plurality of chips, front surfaces of the chips having a first bonding surface; and
a package equipment, configured to fix a second wafer above the plurality of chips, and bond a second bonding surface of the second wafer to the first bonding surface of the plurality of chips.

10. The package system according to claim 9, wherein the wafer processing equipment comprises:
a chuck, wherein the chuck is configured to carry the first wafer; and
a dicing apparatus, wherein the dicing apparatus is configured to dice the first wafer into the plurality of chips.

11. The package system according to claim 9, wherein the package equipment comprises:
a first fixing apparatus, wherein the first fixing apparatus is configured to fix the chips of the first wafer;
an alignment apparatus, configured to align the second wafer with the chips, wherein the first bonding surface of the chips has a first alignment mark, the second bonding surface of the second wafer has a second alignment mark, and the alignment apparatus is further configured to detect the first alignment mark and the second alignment mark, and control the first fixing apparatus to align the first alignment mark with the second alignment mark;
a second fixing apparatus, wherein the second fixing apparatus is configured to fix the second wafer, and the second fixing apparatus is located above the first fixing apparatus; and
a package chamber, wherein the package chamber comprises a gas injection apparatus and a gas extraction apparatus, and the first fixing apparatus, the second fixing apparatus, and the alignment apparatus are disposed in the package chamber.
